(19) United States
(12) Patent Application Publication
(10) Pub. No.: US 2016/0109306 A1
(43) Pub. Date: Apr. 21, 2016

(54) PIEZOELECTRIC FORCE MEASURING DEVICE HAVING INTEGRATED WEAR-PROTECTION AND ANTI-FRICTIONAL PROPERTIES

(71) Applicant: OERLIKON SURFACE SOLUTIONS AG,, Trubbach (CH)

(72) Inventors: Albert Peter Gerhard Janssen, Chur (CH); Oliver Gstoehl, Balzers (LI)

(73) Assignee: Oerlikon Surface Solutions AG, Trubbach, Trubbach (CH)

(21) Appl. No.: 14/442,201

(22) PCT Filed: Oct. 22, 2013
(86) PCT No.: PCT/EP2013/003177

§ 371 Date: May 12, 2015

(30) Foreign Application Priority Data
Nov. 13, 2012 (DE) 10 2012 022 113.4

(51) Int. Cl. G01L 1/16; C23C 14/14; C23C 14/35; C23C 16/06

(52) U.S. Cl. CPC G01L 1/16; C23C 16/06; C23C 14/14; C23C 14/35

(57) ABSTRACT

A force measuring device including a crystalline layer with piezoelectric properties. The layer is arranged on at least part of a surface of a solid state actuator (or carrier). The device also includes at least one wear-protection layer with anti-frictional properties. The piezoelectric layer includes crystalline aluminium nitride having a hexagonal crystal structure with a pronounced crystal orientation (002), at least one electrically conductive layer being applied between the surface of the solid-state actuator and the crystalline aluminium nitride layer. The conductive layer is preferably a metal layer consisting of at least one metal, which when oxidized, forms an electrically insulating oxide that is mechanically and thermally more stable than molybdenum(VI) oxide (Mo03).

The present invention relates to a force measuring device, comprising a layer arranged on a solid-state actuator and having piezoelectric properties and at least one wear-protection layer with anti-friction properties, wherein the piezoelectric layer consists of crystalline aluminium nitride having a hexagonal crystal structure with a pronounced crystal orientation (002). Crystalline is to be regarded here as non-X-ray amorphous. The term “crystalline” can especially mean nanocrystalline and/or microcrystalline and/or polycrystalline and/or monocrystalline.

### DESCRIPTION OF THE PRIOR ART

Sensor technology designates in general technology the science and the application of the sensors for measuring and controlling changes in systems.

The field of technical “sensor technology” is delimited in different ways in the German-speaking countries, which partly relates exclusively to sensor elements of measurement engineering, and partly exclusively to binary, i.e. switching, systems (e.g. light barriers). Others also include laboratory and industrial measuring systems for automation. The common feature in technical sensor technology is that it concerns technical products which usually convert non-electrical measurement quantities into electrical signals.

Measurement engineering concerns devices and methods for determining (measuring) physical quantities such as length, mass, force, pressure, electrical current, temperature or time. The continuous measurement of such physical quantities can be used for gaining knowledge and monitoring the state of stressed or loaded surfaces, which are relevantly important for controlling and optimising processing processes.

If such physical quantities are measured on the surface of machine components, such measuring apparatuses for determining the current state quantities must be sufficiently wear-proof in order to withstand the strong forces which can occur on the working surfaces of machine components. Depending on the application in frictional pairings for example, they should simultaneously offer low frictional resistance in combination with the electrical functions.

It is known from the patent specification EP 1058106 to arrange at least one thin-film sensor on the surface of at least one of the rolling contact elements of a roller pairing with two pressure-loaded rolling contact elements running in opposite directions of each other. The thin-film sensor according to EP 1058106 comprises a tribological functional layer which seals the sensor to the outside, and a sensory layer which is arranged between the surface of the rolling contact element and the tribological functional layer. If the surface of the rolling contact element is not electrically insulating, it is necessary to apply an insulating layer between the surface of the rolling contact element and the sensor layer. It is noted that several sensors for different parameters (e.g. temperature, wear and tear, force or pressure applied to the surface) can be introduced into the sensor layer. It is also noted that the sensor layer can also be structured three-dimensionally by means of laser-lithographic methods and the individual layers can be produced by means of a photolithographic methods. The individual sensors can advantageously be formed as a multifunctional sensor, in which different sensors can be produced from a layer material of the sensor layer by adapted shaping of the sensors and the conductor structures. Piezoresistive or also piezoelectric thin-film sensors are suitable inter alia in this connection as sensors (according to EP 1058106). A further insulating layer can be introduced between the sensor layer and the tribological functional layer so that the sensor layer is also insulated against the surface of the element of the roller pairing. The tribological functional layer can advantageously consist of diamond-like amorphous layer systems based on carbon such as DLC or Me:DLC, from titanium nitride or chromium nitride. It is stated that for producing the individual layers CVD or PVD coating methods are applied, wherein the layer thicknesses are typically between 1 μm and 10 μm.

EP 1058106 does not provide any information concerning the nature and composition of such piezoresistive or piezoelectric layers.

The patent specification EP2013598 discloses a force measuring apparatus which comprises an amorphous carbon layer with piezoresistive properties which is arranged on a substrate, wherein the substrate is selected from the group consisting of solid-state actuators, piezo-stack actuators, electromagnetic, hydraulic and/or pneumatic actuators. One disadvantage of the force-measuring apparatus disclosed in EP2013598 is the temperature sensitivity of the carbon layers, which on the one hand limits the application of such sensors due to their limited thermal loadability to temperatures of not more than 150° C. or not more than 200° C., and on the other hand require the use of an additional temperature sensor for the measurement of temporally rapidly changing forces in order to take into account the influence of the temperature on the electrical resistance of the amorphous carbon layer. A further disadvantage of such piezoresistive carbon layer sensors is the necessity of using a current flow in order to enable measuring the resistance of the piezoresistive layer.

Piezoelectric thin-film layers are increasingly also used as active sensor materials. It is possible by means of semiconductor technologies to deposit these active piezoelectric thin films on silicon. This usually concerns zinc oxide (ZnO) or aluminium nitride (AlN). It was published recently for example that ISIT is dealing intensively in the field of microsystem technology with the deposition and integration of thin films of the two piezoelectric materials of aluminium nitride and lead zirconate titanate (PZT). It is possible according to ISIT to deposit AlN with layer thicknesses of up to 2 μm by means of reactive magnetron sputtering. ISIT further reports on a piezoelectric modulus of e31,f: −1.3 C/m² from the deposited AlN layers (with typical layer thicknesses of 500 nm to 2000 nm). According to information supplied by ISIT, the piezoelectric modulus e31,f was measured by using a four-point bending measurement system. ISIT further stated that sputtered molybdenum and/or vacuum-deposited platinum were used as the bottom electrode material.

The inventors have determined however that such AlN layers deposited on molybdenum and/or platinum which are used in microsystems show insufficient adhesive strength for tribological applications and are therefore not suitable for tribological stresses.

### OBJECT OF THE PRESENT INVENTION

It is the object of the present invention to provide a force measuring apparatus which allows the measurement of the force applied to a specific surface of a tribologically loaded component by means of using the piezoelectric principle and simultaneously provides the surface of the component with sufficient wear protection and good anti-friction properties.

### DESCRIPTION OF THE PRESENT INVENTION

This object is achieved by a force measuring apparatus according to claim 1 of the present invention.

The force measuring apparatus in accordance with the present invention comprises a crystalline layer with piezoelectric properties, said layer being arranged on at least part of a surface of a solid-state actuator (substrate), and at least one wear-protection layer with anti-frictional properties, wherein the piezoelectric layer consists of crystalline aluminium nitride having a hexagonal crystal structure with a pronounced crystal orientation (002), wherein at least one electrically conductive layer is applied between the surface of the solid-state actuator and the crystalline aluminium nitride layer, said conductive layer preferably being a metal layer consisting of at least one metal, which when oxidised forms an electrically insulating oxide which is mechanically and thermally more stable than molybdenum (VI) oxide (MoO₃).

A piezoelectric ceramic, which in this case is the aluminium nitride layer, directly converts mechanical energy into electrical energy. It is necessary for the measurement of the generated electrical signals to install electrical contacts, which are usually deposited as metallic layers or electrode layers. Such electrode layers are made of molybdenum and/or platinum according to the prior art.

The inventors have determined however that the use of molybdenum and/or platinum for producing the electrode layers (beneath and on the aluminium nitride layer) results in insufficient wear protection of the tribologically loaded surfaces (on which the force is measured) despite the use of wear protection made from DLC (DLC is the abbreviation of the term Diamond Like Carbon). Said insufficient wearing resistance could be caused at least partly by insufficient adhesive strength or insufficient cohesion within the sensor layer system. The inventors have therefore tried other materials for producing the electrode layers. During their search for a respective solution, the inventors noticed surprisingly that by using titanium for producing the electrode layers a considerably improved wearing strength of the sensor layer system is achieved, and despite the much lower electrical conductivity of titanium in comparison with molybdenum and platinum it is exceptionally well-suited as an electrode layer for piezoelectric aluminium nitride layers.

Aluminium and aluminium-chromium alloys have also proven in this context to be highly suitable materials for the production of electrode layers.

A further advantage for the use of titanium, aluminium and/or aluminium-chromium for producing the electrode layers is that both titanium and also aluminium form electrically insulating oxides, which in comparison with the oxides which are formed from molybdenum and platinum not only adhere in a better mechanical way to the base but are also thermally more stable. This ensures improved adhesive strength of the sensor layer system on the one hand, which leads to increased wearing resistance. It is possible on the other hand that when the surface of an electrode layer (e.g. the surface of the electrode layer which is closer to the surface of the force measuring apparatus or closer to the tribological layer) is exposed by a scratch or during the application, it will oxidise itself and form a solid electrically insulating oxide (e.g. TiO₂ or Al₂O₃) which remains on the surface and thus acts in a self-healing manner.

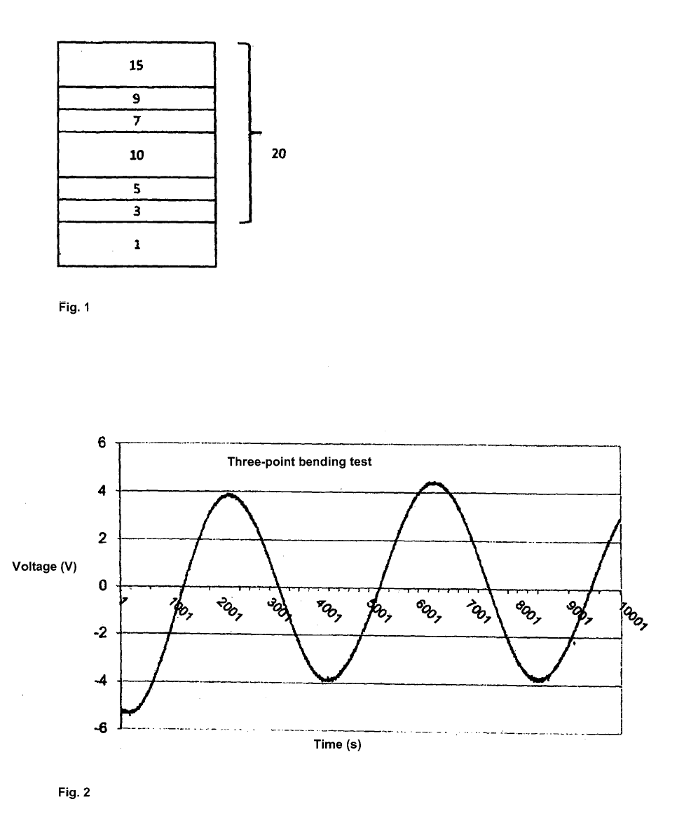

A preferred variant of the present invention is shown in FIG. 1. An electrically conductive substrate 1 is shown in FIG. 1, from which a sensor layer system 20 according to the present invention is deposited. The sensor layer system 20 comprises the following:
An insulating layer 3 in order to prevent electrical contact between the substrate and the force measuring apparatus.
An electrically conductive layer 5, which is preferably a metallic layer made of at least one metal, which when oxidised forms an electrically insulating oxide which is mechanically and thermally more stable than molybdenum (VI) oxide (MoO₃), preferably made of titanium and/or aluminium and/or aluminium-chromium.
A piezoelectric layer 10 made of crystalline aluminium nitride, having a hexagonal crystal structure with pronounced crystal orientation (002).
An electrically conductive layer 7, which is preferably a metallic layer made of at least one metal, which when oxidised forms an electrically insulating oxide which is mechanically and thermally more stable than molybdenum (VI) oxide (MoO₃), preferably made of titanium and/or aluminium and/or aluminium-chromium.
An insulating layer 9, which could be produced similar to the layer 3.
A tribological layer, having wear protection and good anti-frictional properties, preferably made of DLC or Me:DLC (Me:DLC is the abbreviation of the term Metal containing Diamond Like Carbon).

In a preferred embodiment of the present invention, the insulating layers 3 and 9 are made of a material containing aluminium oxide, preferably aluminium oxide (Al₂O₃). These layers are preferably deposited with a layer thickness of not more than 1.5 μm, more preferably between 0.4 and 0.6 μm.

In order to further improve the adhesive strength within the sensor layer system 20 (formed by all layers deposited on the substrate), graded layers can be deposited between the electrode layers and the insulating layers, in which the metal content is varied gradually for example, especially when the layers 3 and 9 are made of Al₂O₃ for example or mostly contain Al₂O₃, and the layers 5 on 7 are made of Al or mostly contain Al.

Al₂O₃ can be applied at first to the substrate by reactive sputtering for example. Atomising from an aluminium target is carried out at first, under the addition of oxygen as a reactive gas. The flow of oxygen is gradually decreased until no reactive gas is available any more and metallic aluminium is deposited. Finally, nitrogen is gradually introduced as a reactive gas and with increasing flow as a reactive gas, as a result of which the piezoelectric AlN is deposited. Finally, the nitrogen flow is gradually decreased to zero again, so that metallic aluminium is deposited again. Finally, an oxygen flow is gradually established in a rising manner again, so that Al₂O₃ is deposited. This is finally followed by the deposition of the tribological layer.

The electrode layers 5 on 7 are made of titanium in a further preferred embodiment of the present invention. These layers preferably have a layer thickness of not more than 1 μm, preferably between 0.2 and 0.6 μm.

In a further preferred embodiment of the present invention, the piezoelectric layer 10 and the tribological layer 15 have a layer thickness of not more than 5 μm, preferably between 1 μm and 3 μm, more preferably between 2 μm and 3 μm.

In a further preferred embodiment of the present invention, the tribological layer 15 is a DLC layer or a carbon layer containing tungsten carbide (WC/C layer), or a combination thereof.

All layers which form the sensor layer system according to the present invention are preferably produced by means of PVD and/or PACVD techniques (PVD and PACVD are the respective abbreviations of the terms Physical Vapour Deposition and Plasma Assisted Chemical Vapour Deposition). At least one of the layers 3, 5, 10, 7 9 is preferably deposited by means of MS and/Or HIPIMS techniques (MS and HIPIMS are the respective abbreviations of the terms Magnetron Sputtering and High Power Impulse Magnetron Sputtering).

A force measuring apparatus in accordance with the present invention can especially be used for remote monitoring of components such as ball bearings which are used among other things in windmill gears, aircraft construction and safety equipment.

The potential difference between the two electrode layers can be measured continuously without any problems by using a voltage measuring device. The voltage measuring device can be connected for example to an inner bearing race coated with a sensor layer system according to the present invention.

FIG. 2 shows the recorded electrical signal of a force measuring apparatus in accordance with the present invention, which was measured in performing a three-point bending test. The deformation range was varied between 10 and 1000 ppm (ppm=1 mm/1000000 mm) in this test.

What is claimed is:

1. A force measuring device, comprising a sensor layer system (20) on at least a part of a surface of a substrate (1), and the sensor layer system (20) comprises at least one crystalline layer (10) with piezoelectric properties which is applied to the solid-state actuator and comprises at least one wear-protection layer (15) with anti-frictional properties, wherein the piezoelectric layer (10) consists of crystalline aluminium nitride having a hexagonal crystal structure with pronounced crystal orientation (002), characterized in that at least one electrically conductive layer (5) is applied between the surface of the solid-state actuator (1) and the crystalline aluminium nitride layer (10).

2. A force measuring apparatus according to claim 1, characterized in that the conductive layer (5) consists of titanium and/or aluminium and/or aluminium-chromium, or at least mainly contains titanium and/or aluminium and/or aluminium-chromium.

3. A force measuring apparatus according to claim 1, characterized in that the sensor layer system (20) comprises an insulating layer (3).

4. A force measuring apparatus according to claim 1, characterized in that the sensor layer system (20) comprises an electrically conductive layer (7) which is preferably a metallic layer made of at least one metal, which when oxidised forms an electrically insulating oxide which is mechanically and thermally more stable than molybdenum (VI) oxide (MoO₃), preferably consisting of titanium and/or aluminium and/or aluminium-chromium, or mainly containing titanium and/or aluminium and/or aluminium-chromium.

5. A force measuring apparatus according to claim 1, characterized in that the sensor layer system (20) comprises an insulating layer (9) which is preferably formed similarly to the layer (3).

6. A force measuring apparatus according to claim 1, characterized in that the layer (15) consists of DLC or Me:DLC, or mainly contains DLC or Me:DLC, preferably of or with WC:DLC.

7. A force measuring apparatus according to claim 1, characterized in that at least one graded layer is deposited between at least one of the electrode layers and at least one of the insulating layers (accordingly between 5 and 3 and/or between 7 and 9), in which at least the concentration of an element is gradually varied which is contained both in the layer 5 and also in the layer 3 and/or both in the layer 7 and also in the layer 9.

8. A force measuring apparatus according to claim 1, characterized in that at least one of the insulating layers (3 and/or 9) is produced from a material containing aluminium oxide, preferably Al₂O₃.

9. A method for depositing a sensor layer system (20) for producing a force measuring apparatus according to claim 1, characterized in that all layers of the sensor layer system (20) are deposited by means of PVD and/or PACVD techniques.

10. A method for depositing a sensor layer system (20) according to claim 9, characterized in that at least one layer of the sensor layer system (20) is deposited by means of MS and/or HIPIMS techniques.

11. The application of a force measuring apparatus according to claim 1 for monitoring the state of the surfaces of components subjected to tribological loading, which components are used in windmill gears, aircraft construction and safety equipment.

12. A force measuring device according to claim 1, where said conductive layer contains at least one metallic layer consisting of at least one metal, which when oxidised forms an electrically insulating oxide which mechanically adheres to the base and is thermally more stable than molybdenum (VI) oxide (MoO₃).
